(19) United States
(12) Patent Application Publication
(10) Pub. No.: US 2026/0096094 A1
(43) Pub. Date: Apr. 2, 2026

(54) SEMICONDUCTOR DEVICE WITH THREE-DIMENSIONAL MEMORY ARRAY

(71) Applicant: SAMSUNG ELECTRONICS CO., LTD., Suwon-si (KR)

(72) Inventors: Taegyu KANG, Suwon-si (KR); Jinwoo HAN, Suwon-si (KR)

(73) Assignee: SAMSUNG ELECTRONICS CO., LTD., Suwon-si (KR)

(21) Appl. No.: 19/282,225

(22) Filed: Jul. 28, 2025

(30) Foreign Application Priority Data
Oct. 2, 2024 (KR) 10-2024-0134271

(51) Int. Cl. H10B 12/00; H01L 23/528

(52) U.S. Cl. CPC H10B 12/488; H10B 12/482; H10W 20/43

(57) ABSTRACT

Provided is a semiconductor device including a substrate, a plurality of word lines separate from each other in a vertical direction and in a first horizontal direction and extending in a second horizontal direction, a plurality of bit lines separate from each other in the second horizontal direction on a first side of the plurality of word lines and extending in the vertical direction, a plurality of capacitor structures separate from each other in the second horizontal direction on a second side of the plurality of word lines and extending in the first horizontal direction, and a plurality of word line pads separate from each other in the vertical direction, extending in the first horizontal direction, and respectively connected to the plurality of word lines, wherein the plurality of word line pads have a same length in the first horizontal direction.

### CROSS-REFERENCE TO RELATED APPLICATION

This application is based on and claims priority to Korean Patent Application No. 10-2024-0134271, filed on October 2, 2024, in the Korean Intellectual Property Office, the disclosure of which is incorporated by reference herein in its entirety.

### BACKGROUND

### 1. Field

The disclosure relates to a semiconductor device, and more particularly, to a semiconductor device including a three-dimensional (3D) semiconductor memory element.

### 2. Description of Related Art

As electronic products are required to have smaller sizes, multi-functions, and higher performance, high-capacity semiconductor memory elements are required, and an increased degree of integration is required to provide high-capacity semiconductor memory elements. Because the degree of integration of two-dimensional (2D) semiconductor memory elements of the related art is mainly determined by the area occupied by a unit memory cell, the degree of integration of 2D semiconductor memory elements has increased but is still limited. Accordingly, a semiconductor device including a 3D semiconductor memory element, in which memory capacity is increased by stacking a plurality of memory cells in a vertical direction on a substrate, has been proposed.

### SUMMARY

Provided is a semiconductor device having an improved degree of integration by including a plurality of word line pads that have the same size rather than having a stair shape.

According to an aspect of the disclosure, a semiconductor device includes: a substrate; a plurality of word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction; a plurality of bit lines extending in the vertical direction and separate from each other in the second horizontal direction on a first side of the plurality of word lines; a plurality of capacitor structures extending in the first horizontal direction and separate from each other in the second horizontal direction on a second side of the plurality of word lines, the second side of the plurality of word lines being opposite to the first side of the plurality of word lines; and a plurality of word line pads separate from each other in the vertical direction, extending in the first horizontal direction, and respectively connected to the plurality of word lines, wherein the plurality of word line pads have a same length in the first horizontal direction.

According to an aspect of the disclosure, a semiconductor device includes: a substrate; a plurality of first word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction; a plurality of second word lines extending in the second horizontal direction and arranged alternately with the plurality of first word lines in the first horizontal direction; a plurality of bit lines extending in the vertical direction and separate from each other in the second horizontal direction; a plurality of capacitor structures extending in the first horizontal direction and separate from each other in the second horizontal direction; a plurality of first word line pads separate from each other in the vertical direction, wherein each of the plurality of first word line pads extends in the first horizontal direction and is respectively connected to the plurality of first word lines; and a plurality of second word line pads separate from each other in the vertical direction, wherein each of the plurality of second word line pads extends in the first horizontal direction and is respectively connected to the plurality of second word lines, wherein the plurality of first word line pads and the plurality of second word line pads are separate from each other in the second horizontal direction, wherein the plurality of bit lines and the plurality of capacitor structures are between the plurality of first word line pads and the plurality of second word line pads, wherein the plurality of first word line pads have a same length in the first horizontal direction, and wherein the plurality of second word line pads have a same length in the first horizontal direction.

According to an aspect of the disclosure, a semiconductor device includes: a substrate; a peripheral circuit structure on the substrate; and a cell array structure on the peripheral circuit structure, the cell array structure including a plurality of stacked structures, wherein each of the plurality of stacked structures includes: a plurality of word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction; a plurality of bit lines extending in the vertical direction and separate from each other in the second horizontal direction on a first side of the plurality of word lines; and a plurality of capacitor structures extending in the first horizontal direction and separate from each other in the second horizontal direction on a second side of the plurality of word lines, the second side of the plurality of word lines being opposite to the first side of the plurality of word lines, and wherein the cell array structure further includes: a plurality of word line pads separate from each other in the vertical direction, wherein the plurality of word line pads are on two sides of the plurality of stacked structures in the second horizontal direction, extend to have a same length in the first horizontal direction, and are respectively connected to the plurality of word lines; and a plurality of word line contacts separate from each other in the first horizontal direction and respectively connected to the plurality of word lines through the plurality of word line pads.

The disclosure is not limited to the foregoing aspects and features, and other aspects and features not mentioned will be clearly understood by those skilled in the art from the following descriptions.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram illustrating a semiconductor device according to one or more embodiments;

FIG. 2A is a perspective view schematically illustrating a semiconductor device according to one or more embodiments;

FIG. 2B is a cross-sectional view illustrating a portion of a cross-section taken along line X1-X1’ of FIG. 2A;

FIG. 2C is a cross-sectional view illustrating a portion of a cross-section taken along line X2-X2’ of FIG. 2A;

FIG. 3 is a plan view schematically illustrating a semiconductor device according to one or more embodiments;

FIG. 4 is a configuration diagram illustrating some components of a semiconductor device according to one or more embodiments;

FIG. 5 is an enlarged view of region EX1 of FIG. 4;

FIGS. 6A, 6B, and 6C are configuration diagrams illustrating some components of a semiconductor device according to one or more embodiments;

FIG. 7 is a plan view schematically illustrating a semiconductor device according to one or more embodiments;

FIGS. 8A, 8B, 8C and 8D are plan views schematically illustrating a semiconductor device according to one or more embodiments; and

FIGS. 9A, 9B, and 9C are configuration diagrams illustrating some components of a semiconductor device according to one or more embodiments.

### DETAILED DESCRIPTION

Hereinafter, one or more embodiments are described in detail with reference to the accompanying drawings. Like reference numerals are used for like components in the drawings, and redundant descriptions thereof are omitted.

Terms such as “unit”, “module”, “member”, and “block” may be embodied as hardware or software. As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

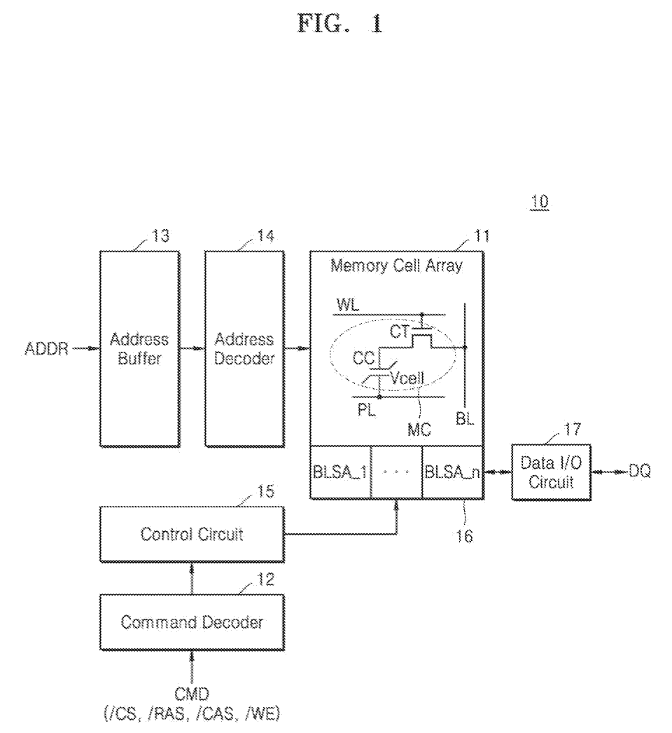

FIG. 1 is a block diagram illustrating a semiconductor device 10 according to one or more embodiments.

Referring to FIG. 1, the semiconductor device 10 may include a memory cell array 11, a command decoder 12, an address buffer 13, an address decoder 14, a control circuit 15, a sense amplifier 16, and a data input/output (I/O) circuit 17.

The semiconductor device 10 may be implemented as a DRAM that senses, as data, a cell voltage Vcell stored in a memory cell MC.

The semiconductor device 10 may input or output data DQ in response to a command CMD and an address ADDR received from an external device (e.g., a central processing unit (CPU) or a memory controller).

The memory cell array 11 may include a plurality of memory cells MC. The memory cell array 11 may include a plurality of word lines WL, a plurality of bit lines BL, and a plurality of plate lines PL that are connected to the memory cells MC.

Each of the memory cells MC may include a cell transistor CT and a cell capacitor CC. A gate terminal of the cell transistor CT may be connected to one of the word lines WL of the memory cell array 11. A first terminal of the cell transistor CT may be connected to one of the bit lines BL of the memory cell array 11. A second terminal of the cell transistor CT may be connected to a first terminal of the cell capacitor CC. A second terminal of the cell capacitor CC may be connected to one of the plate lines PL of the memory cell array 11. The cell capacitor CC may store electric charges of a capacity corresponding to data.

The memory cell MC may store, in the cell capacitor CC, a cell voltage Vcell having a size that specifies data.

The command decoder 12 may determine a command CMD input thereto by referring to a chip select signal /CS, a row address strobe signal /RAS, a column address strobe signal /CAS, a write enable signal /WE, etc., which are applied from an external device. The command decoder 12 may generate control signals corresponding to the command CMD. The command CMD may include an active command, a read command, a write command, a precharge command, etc.

The address buffer 13 may receive an address ADDR applied from an external device. The address ADDR may include a word line address that addresses some of the word lines WL connected to the memory cell array 11, a bit line address that addresses some of the bit lines BL connected to the memory cell array 11, and a plate address that addresses some of the plate lines PL connected to the memory cell array 11. The address buffer 13 may transmit each of the word line address, the bit line address, and the plate line address to the address decoder 14.

The address decoder 14 may include a word line decoder, a bit line decoder, and a plate line decoder that select, in response to a received address ADDR, a word line WL, a bit line BL, and a plate line PL of the memory cell MC to be accessed.

The word line decoder may decode a word line address and activate a word line WL of the memory cell MC that corresponds to the word line address. The bit line decoder may decode a bit line address and provide a bit line select signal for selecting a bit line BL of the memory cell MC that corresponds to the bit line address. The plate line decoder may decode a plate line address and provide a plate line select signal for selecting a plate line PL of the memory cell MC that corresponds to the plate line address.

The control circuit 15 may control the sense amplifier 16 under control by the command decoder 12. The control circuit 15 may control an operation of sensing the cell voltage Vcell of the memory cell MC by the sense amplifier 16. The control circuit 15 may control the sense amplifier 16 to perform a precharge operation, a charge sharing operation, a sensing operation, etc.

The sense amplifier 16 may include a plurality of sense amplifiers. The sense amplifier 16 including the plurality of sense amplifiers, that is, a plurality of bit line sense amplifiers BLSA_1 to BLSA_n, may sense, as data, electric charges stored in the memory cell MC. Also, the sense amplifier 16 may transmit the sensed data to the data I/O circuit 17 so that the sensed data is output to the outside of the semiconductor device 10 through a data pad(s) DQ.

The data I/O circuit 17 may receive, from the outside, data DQ to be written in the memory cell MC and transmit the data DQ to the memory cell array 11. The data I/O circuit 17 may output bit data, which is sensed by the sense amplifier 16, as read data to the outside through the data pad(s) DQ.

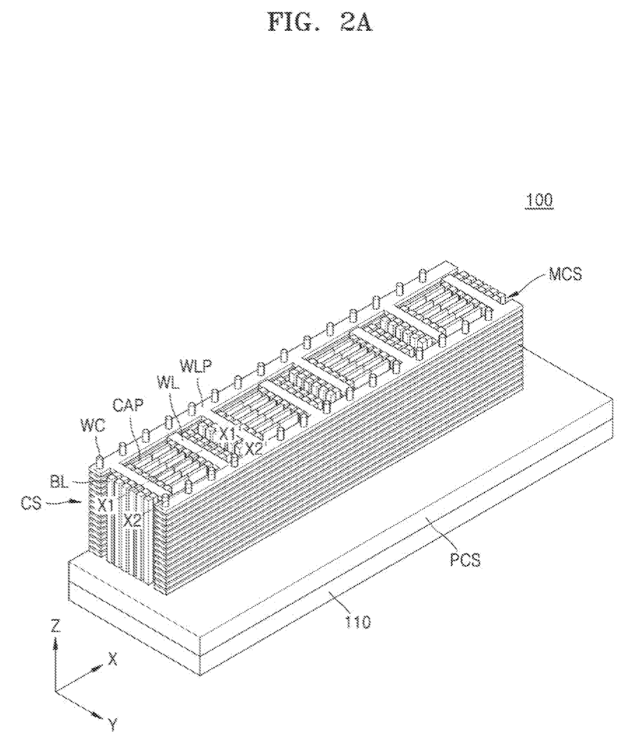

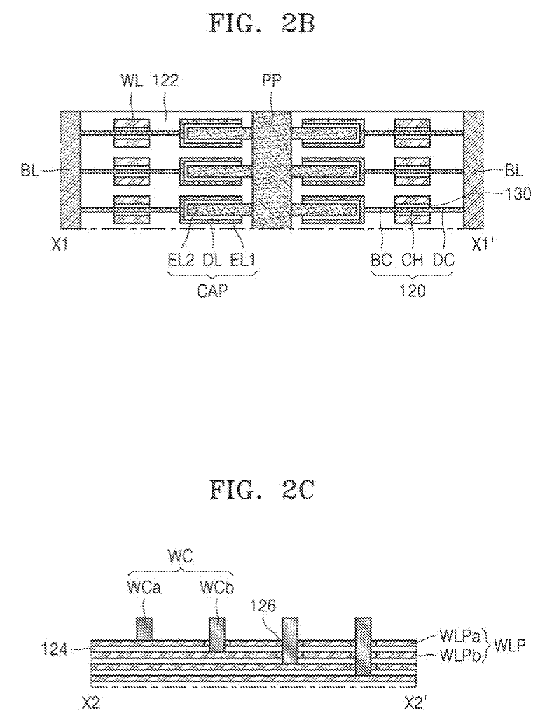

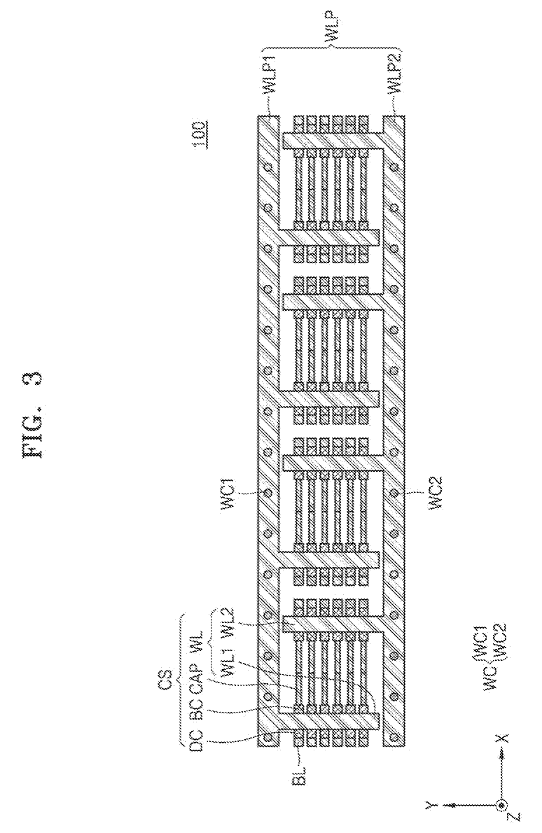

FIG. 2A is a perspective view schematically illustrating a portion of a semiconductor device 100 according to one or more embodiments. FIG. 2B is a cross-sectional view illustrating a portion of a cross-section taken along line X1-X1’ of FIG. 2A. FIG. 2C is a cross-sectional view illustrating a portion of a cross-section taken along line X2-X2’ of FIG. 2A. FIG. 3 is a plan view schematically illustrating a portion of the semiconductor device 100 according to one or more embodiments.

Referring to FIGS. 2A to 2C and FIG. 3, the semiconductor device 100 may include a substrate 110, a peripheral circuit structure PCS, and a cell array structure MCS.

The substrate 110 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium. The substrate 110 may be provided as a bulk wafer or an epitaxial layer. In one or more embodiments, the substrate 110 may include a silicon-on-insulator (SOI) substrate or a germanium-on-insulator (GeOI) substrate.

The peripheral circuit structure PCS may be provided on the substrate 110. The peripheral circuit structure PCS may include peripheral circuit transistors arranged on the substrate 110 and peripheral circuit wiring structures for connecting the peripheral circuit transistors to each other or connecting the peripheral circuit transistors to components in the cell array structure MCS.

The peripheral circuit transistors may constitute a plurality of peripheral circuits. The plurality of peripheral circuits including the peripheral circuit transistors may include the various circuits described with reference to FIG. 1. For example, the plurality of peripheral circuits may include the command decoder 12, the address buffer 13, the address decoder 14, the control circuit 15, the sense amplifier 16, and the data I/O circuit 17 illustrated in FIG. 1.

The cell array structure MCS may be arranged on the peripheral circuit structure PCS. The cell array structure MCS may include a plurality of stacked structures CS, and the plurality of stacked structures CS may each include a plurality of word lines WL, a plurality of bit lines BL, and a plurality of capacitor structures CAP. The plurality of stacked structures CS may be arranged apart from (i.e., separate from) each other in a first horizontal direction (X direction) on the peripheral circuit structure PCS.

Referring to FIGS. 2A and 2B, the plurality of word lines WL may be stacked or aligned in a vertical direction (Z direction) on the peripheral circuit structure PCS. The plurality of word lines WL stacked or aligned in the vertical direction (Z direction) may be separate from each other in the vertical direction (Z direction). The plurality of word lines WL may each extend in a second horizontal direction (Y direction). The plurality of word lines WL may correspond to the plurality of word lines WL included in the memory cell array 11 of the semiconductor device 10 illustrated in FIG. 1.

The plurality of word lines WL may each extend in the second horizontal direction (Y direction) and may be separate from each other in the vertical direction (Z direction) on a semiconductor pattern 120. For example, the plurality of word lines WL may have a double word line structure including a pair of word lines that are apart from each other in the vertical direction (Z direction) with the semiconductor pattern 120 therebetween. In one or more embodiments, the plurality of word lines WL may have a single word line structure including only one word line arranged on the semiconductor pattern 120. In another embodiment, the plurality of word lines WL may have a gate-all-around (GAA) structure that surrounds a plurality of semiconductor patterns 120 and extends in the second horizontal direction (Y direction).

The plurality of word lines WL may include at least one of a doped semiconductor material (doped silicon, doped germanium, etc.), a conductive metal nitride (titanium nitride, tantalum nitride, etc.), a metal (tungsten, titanium, tantalum, etc.), and a metal-semiconductor compound (tungsten silicide, cobalt silicide, titanium silicide, etc.).

A gate insulating layer 130 may be arranged between the word line WL and the semiconductor pattern 120. The gate insulating layer 130 may include at least one selected from a high-k dielectric material, which has a higher dielectric constant than silicon oxide, and a ferroelectric material. In one or more embodiments, the gate insulating layer 130 may include at least one material selected from hafnium oxide (HfO), hafnium silicate (HfSiO), hafnium oxynitride (HfON), hafnium silicon oxynitride (HfSiON), lanthanium oxide (LaO), lanthanium aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

The plurality of semiconductor patterns 120 may be stacked or arranged in the vertical direction (Z direction) on the peripheral circuit structure PCS. The plurality of semiconductor patterns 120 may extend in the first horizontal direction (X direction) and may be separate from each other in the second horizontal direction (Y direction). The plurality of semiconductor patterns 120 may have a line shape or a bar shape extending in the first horizontal direction (X direction).

The plurality of semiconductor patterns 120 may each include a channel region CH between a direct contact DC and a buried contact BC, where the direct contact DC, the channel region CH, and the buried contact BC are arranged in the first horizontal direction (X direction). The direct contact DC may be connected to the bit line BL, and the buried contact BC may be connected to the capacitor structure CAP. An ohmic metal layer including metal silicide, etc. may be further formed between the direct contact DC and the bit line BL, and between the buried contact BC and the capacitor structure CAP.

In one or more embodiments, the plurality of semiconductor patterns 120 may include, for example, an undoped semiconductor material or a doped semiconductor material. In one or more embodiments, the plurality of semiconductor patterns 120 may include polysilicon. In one or more embodiments, the plurality of semiconductor patterns 120 may include an amorphous metal oxide, a polycrystalline metal oxide, or a combination of an amorphous metal oxide and a polycrystalline metal oxide. For example, the plurality of semiconductor patterns 120 may include at least one of In-Ga-based oxide (IGO), In-Zn-based oxide (IZO), and In-Ga-Zn-based oxide (IGZO). In one or more embodiments, the plurality of semiconductor patterns 120 may include a two-dimensional (2D) material semiconductor. For example, the 2D material semiconductor may include MoS2, WSe2, graphene, carbon nanotubes, or a combination thereof.

The direct contacts DC and the buried contacts BC of the plurality of semiconductor patterns 120 may each be doped with a first impurity. The channel region CH may be doped with a second impurity that is different from the first impurity. For example, the first impurity may cause each of the direct contact DC and the buried contact BC to have a first conductivity type, and the second impurity may cause the channel region CH to have a second conductivity type that is different from the first conductivity type. For example, the first conductivity type may be n-type and the second conductivity type may be p-type, but are not limited thereto. For example, the first conductivity type may be p-type, and the second conductivity type may be n-type. When the first conductivity type is n-type, the first impurity may be phosphorus (P), arsenic (As), or antimony (Sb), and when the second conductivity type is p-type, the second impurity may be boron (B), aluminum (Al), gallium (Ga), or indium (In).

The plurality of capacitor structures CAP may be arranged between the plurality of word lines WL separate from each other in the first horizontal direction (X direction). The plurality of capacitor structures CAP may extend in the first horizontal direction (X direction) between the plurality of word lines WL. Also, the plurality of capacitor structures CAP may be stacked or aligned in the vertical direction (Z direction) between the plurality of word lines WL. The plurality of capacitor structures CAP may correspond to the plurality of cell capacitors CC included in the memory cell array 11 of the semiconductor device 10 illustrated in FIG. 1.

The plurality of capacitor structures CAP may each include a first electrode EL1, a second electrode EL2 surrounding the first electrode EL1, and a dielectric film DL arranged between the first electrode EL1 and the second electrode EL2. For example, the first electrode EL1 may have an empty cylinder shape, and the second electrode EL2 may fill the inside of the first electrode EL1.

The first electrode EL1 and the second electrode EL2 may each include at least one of a metal material such as titanium, tantalum, tungsten, copper, or aluminum, a conductive metal nitride such as titanium nitride or tantalum nitride, and a doped semiconductor material such as doped silicon or doped germanium. Also, the dielectric film DL may include a high-k dielectric material. The high-k dielectric material may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

A plate electrode PP may be arranged to extend in the vertical direction (Z direction) on one side of the capacitor structure CAP. The second electrode EL2 of the capacitor structure CAP may be electrically connected to the plate electrode PP. For example, a plurality of second electrodes EL2 separate from each other in the vertical direction (Z direction) and a plurality of second electrodes EL2 separate from each other in the second horizontal direction (Y direction) may be commonly connected to the plate electrode PP.

The buried contact BC may be arranged between each of the plurality of word lines WL and each of the plurality of capacitor structures CAP. The buried contact BC may be in contact with the channel region CH of one semiconductor pattern 120 selected from among the plurality of semiconductor patterns 120 on one side and may be in contact with one capacitor structure CAP selected from among the plurality of capacitor structures CAP on another side facing the one side in the first horizontal direction (X direction). The selected one word line WL and the selected one capacitor structure CAP may be connected to each other by the buried contact BC. In this regard, the buried contact BC may denote, for example, a source/drain region arranged between each of the plurality of word lines WL and each of the plurality of capacitor structures CAP.

The plurality of bit lines BL may be separate from the plurality of capacitor structures CAP in the first horizontal direction (X direction) with the plurality of word lines WL therebetween. The plurality of bit lines BL may each extend in the vertical direction (Z direction). Also, the plurality of bit lines BL may each be arranged in the second horizontal direction (Y direction). The plurality of bit lines BL may correspond to the plurality of bit lines BL included in the memory cell array 11 of the semiconductor device 10 illustrated in FIG. 1. The plurality of bit lines BL may include a doped semiconductor material, a conductive metal nitride, a metal, a metal-semiconductor compound, or a combination thereof.

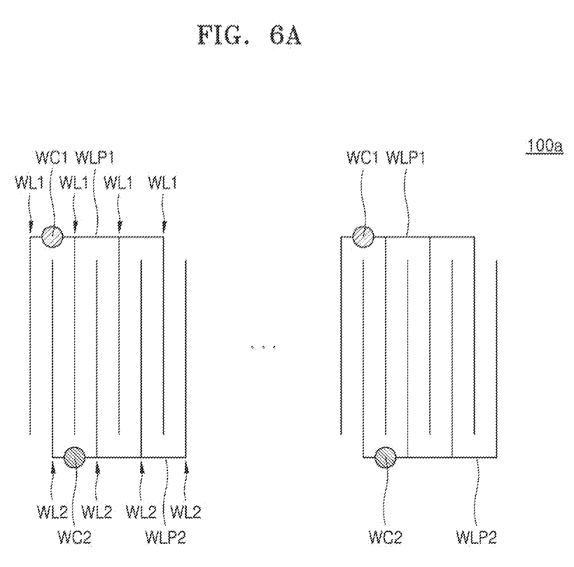

A cell transistor may be formed in a region where the plurality of bit lines BL and the plurality of word lines WL intersect with each other. The cell transistor may correspond to the cell transistor CT included in the memory cell array 11 of the semiconductor device 10 illustrated in FIG. 1. The cell transistor may include a first gate GA1 and a second gate GA2 illustrated in FIG. 5, and a gate dielectric film surrounded by the first gate GA1 and the second gate GA2. The cell transistor, together with the capacitor structure CAP, may constitute a memory cell of the cell array structure MCS.

The direct contact DC may be arranged between each of the plurality of word lines WL and each of the plurality of bit lines BL. The direct contact DC may be in contact with the channel region CH of one semiconductor pattern 120 selected from among the plurality of semiconductor patterns 120 on one side and may be in contact with one bit line BL selected from among the plurality of bit lines BL on another side facing the one side in the first horizontal direction (X direction). The selected one word line WL and the selected one bit line BL may be connected to each other by the direct contact DC. In this regard, the direct contact DC may denote, for example, a source/drain region arranged between each of the plurality of word lines WL and each of the plurality of bit lines BL.

A mold insulating layer 122 may be arranged between two adjacent semiconductor patterns 120 separate from each other in the vertical direction (Z direction), between two adjacent word lines WL separate from each other in the vertical direction (Z direction), and between two adjacent first electrodes EL1 separate from each other in the vertical direction (Z direction). Also, the mold insulating layer 122 may also be arranged between two bit lines BL separate from each other in the second horizontal direction (Y direction). The mold insulating layer 122 may include silicon oxide, silicon oxynitride, silicon nitride, carbon-containing silicon oxide, carbon-containing silicon oxynitride, carbon-containing silicon nitride, or a combination thereof.

A plurality of word line pads WLP may be arranged on one side of each of the plurality of word lines WL. The plurality of word line pads WLP may extend in the first horizontal direction (X direction) on one side of each of the plurality of word lines WL. The plurality of word line pads WLP may be stacked in the vertical direction (Z direction). Each of the plurality of word line pads WLP that are stacked may be positioned at the same vertical level as each of the plurality of word lines WL that are stacked. For example, a word line pad WLP at an uppermost position among the plurality of word line pads WLP may be positioned at the same vertical level as a word line WL at an uppermost position among the plurality of word lines WL, and a word line pad WLP at a lowermost position among the plurality of word line pads WLP may be positioned at the same vertical level as a word line WL at a lowermost position among the plurality of word lines WL.

The plurality of word lines WL may include a plurality of first word lines WL1 and a plurality of second word lines WL2. The plurality of first word lines WL1 may be arranged in a plurality of columns separate from each other in the first horizontal direction (X direction), and the plurality of second word lines WL2 may be arranged in a plurality of columns separate each other in the first horizontal direction (X direction). Also, the plurality of first word lines WL1 and the plurality of second word lines WL2 may be alternately arranged in the first horizontal direction (X direction).

The plurality of word line pads WLP may include a plurality of first word line pads WLP1 and a plurality of second word line pads WLP2. The plurality of first word line pads WLP1 and the plurality of second word line pads WLP2 may each be stacked in the vertical direction (Z direction). The plurality of first word line pads WLP1 and the plurality of second word line pads WLP2 may each extend in the first horizontal direction (X direction).

In a plan view, the plurality of first word line pads WLP1 and the plurality of second word line pads WLP2 may be arranged on two sides of the plurality of stacked structures CS in the second horizontal direction (Y direction). The plurality of first word line pads WLP1 and the plurality of second word line pads WLP2 may be separate from each other in the second horizontal direction (Y direction) with the stacked structure CS therebetween. For example, the plurality of first word line pads WLP1 and the plurality of second word line pads WLP2 may be separate from each other in the second horizontal direction (Y direction) with the plurality of bit lines BL and the plurality of capacitor structures CAP therebetween.

The plurality of first word lines WL1 may be respectively connected to the plurality of first word line pads WLP1. First word lines WL1 positioned at the same vertical level, among the plurality of first word lines WL1 included in each of the plurality of stacked structures CS, may be connected to a first word line pad WLP1 positioned at the corresponding vertical level, among the plurality of first word line pads WLP1. The plurality of second word lines WL2 may be respectively connected to the plurality of second word line pads WLP2. Second word lines WL2 positioned at the same vertical level, among the plurality of second word lines WL2 included in each of the plurality of stacked structures CS, may be connected to a second word line pad WLP2 positioned at the corresponding vertical level, among the plurality of second word line pads WLP2. For example, first word lines WL1 at an uppermost position among the plurality of first word lines WL1 included in each of the plurality of stacked structures CS may be connected to a first word line pad WLP1 at an uppermost position among the plurality of first word line pads WLP1.

The plurality of first word line pads WLP1 may have the same size. The plurality of first word line pads WLP1 may have the same length and the same width. For example, even away from an upper surface of the substrate 110 in the vertical direction (Z direction), the plurality of first word line pads WLP1 may have the same length in the first horizontal direction (X direction). Also, even away from the upper surface of the substrate 110 in the vertical direction (Z direction), the plurality of first word line pads WLP1 may have the same width in the second horizontal direction (Y direction).

The plurality of second word line pads WLP2 may have the same size. The plurality of second word line pads WLP2 may have the same length and the same width. For example, even away from the upper surface of the substrate 110 in the vertical direction (Z direction), the plurality of second word line pads WLP2 may have the same length in the first horizontal direction (X direction). Also, even away from the upper surface of the substrate 110 in the vertical direction (Z direction), the plurality of second word line pads WLP2 may have the same width in the second horizontal direction (Y direction). Also, the plurality of first word line pads WLP1 and the plurality of second word line pads WLP2 may have the same length and the same width, but the disclosure is not limited thereto.

A plurality of word line contacts WC may include a plurality of first word line contacts WC1 and a plurality of second word line contacts WC2. The plurality of first word line contacts WC1 may respectively be arranged on the plurality of first word line pads WLP1, and the plurality of second word line contacts WC2 may respectively be arranged on the plurality of second word line pads WLP2. The plurality of first word line contacts WC1 may respectively pass through the plurality of first word line pads WLP1, and the plurality of second word line contacts WC2 may respectively pass through the plurality of second word line pads WLP2.

Referring to FIG. 2C, the plurality of word line contacts WC may pass through the plurality of word line pads WLP and a plurality of interlayer insulating layers 124. The plurality of word line contacts WC may pass through the plurality of word line pads WLP in the vertical direction (Z direction), and lower surfaces of the plurality of word line contacts WC may each be in contact with one word line pad WLP among the plurality of word line pads WLP. In this regard, the plurality of word line contacts WC may have different lengths in the vertical direction (Z direction). Accordingly, the plurality of word line contacts WC may pass through different numbers of the plurality of word line pads WLP in the vertical direction (Z direction).

One word line contact WC selected from among the plurality of word line contacts WC may be in contact with one word line pad WLP selected from among the plurality of word line pads WLP at a first vertical level. In this case, the selected word line contact WC may pass through a first group of word line pads WLP positioned at a vertical level higher than the first vertical level, among the plurality of word line pads WLP. In this case, the word line contact WC may be apart from and insulated from the first group of word line pads WLP by the interlayer insulating layer 124 and an insulating spacer 126. In this regard, the interlayer insulating layer 124 may include, for example, silicon oxide, silicon oxynitride, silicon nitride, carbon-containing silicon oxide, carbon-containing silicon oxynitride, carbon-containing silicon nitride, or a combination thereof.

The insulating spacer 126 may be arranged between a sidewall of each of the plurality of word line contacts WC and the plurality of word line pads WLP. When one word line contact WC selected from among the plurality of word line contacts WC is in contact with one word line pad WLP selected from the plurality of word line pads WLP at the first vertical level, the selected word line contact WC may be insulated from the first group of word line pads WLP positioned at a vertical level higher than the first vertical level, among the plurality of word line pads WLP. For example, the insulating spacer 126 may be arranged between a sidewall of one word line contact WC selected from among the plurality of word line contacts WC and the first group of word line pads WLP positioned at a vertical level higher than the first vertical level. Accordingly, the first group of word line pads WLP and the selected word line contact WC may be insulated from each other. In this regard, the insulating spacer 126 may include silicon oxide, but is not limited thereto.

For example, one word line contact WCa selected from among the plurality of word line contacts WC may be connected to a word line pad WLPa at an uppermost position among the plurality of word line pads WLP. Also, another one word line contact WCb among the plurality of word line contacts WC may be connected to a word line pad WLPb at a second uppermost position among the plurality of word line pads WLP. In this regard, the selected one word line contact WCa and the other one word line contact WCb may have different lengths in the vertical direction (Z direction). Also, the selected one word line contact WCa and the other one word line contact WCb may pass through different numbers of the plurality of word line pads WLP in the vertical direction (Z direction). The other one word line contact WCb may pass through the word line pad WLPa at the uppermost position in the vertical direction (Z direction) and may be apart and insulated from the word line pad WLPa at the uppermost position by the interlayer insulating layer 124 and the insulating spacer 126. For example, the insulating spacer 126 may be arranged between a sidewall of the other one word line contact WCb and the word line pad WLPa at the uppermost positon.

The plurality of first word line contacts WC1 may pass through the plurality of first word line pads WLP1 in the vertical direction (Z direction), and lower surfaces of the plurality of first word line contacts WC1 may each be in contact with one first word line pad WLP1 among the plurality of first word line pads WLP1. In this regard, the plurality of first word line contacts WC1 may have different lengths in the vertical direction (Z direction). Accordingly, the plurality of first word line contacts WC1 may pass through different numbers of the plurality of first word line pads WLP1 in the vertical direction (Z direction).

The plurality of second word line contacts WC2 may pass through the plurality of second word line pads WLP2 in the vertical direction (Z direction), and lower surfaces of the plurality of second word line contacts WC2 may each be in contact with one second word line pad WLP2 among the plurality of second word line pads WLP2. In this regard, the plurality of second word line contacts WC2 may have different lengths in the vertical direction (Z direction). Accordingly, the plurality of second word line contacts WC2 may pass through different numbers of the plurality of second word line pads WLP2 in the vertical direction (Z direction).

The plurality of first word line contacts WC1 may be separate from each other in the first horizontal direction (X direction) and may be respectively connected to the plurality of first word lines WL1 through the plurality of first word line pads WLP1. The plurality of second word line contacts WC2 may be separate from each other in the first horizontal direction (X direction) and may be respectively connected to the plurality of second word lines WL2 through the plurality of second word line pads WLP2.

Any first word line contact WC1 among the plurality of first word line contacts WC1 may be connected to the plurality of first word lines WL1 positioned at the same vertical level as a first word line pad WLP1 in contact with a lower surface of the any first word line contact WC1, among the plurality of first word line pads WLP1. In this regard, the plurality of first word lines WL1 connected to the any first word line contact WC1 may have the same vertical level.

For example, a first word line WL1 at an uppermost position among the plurality of first word lines WL1 included in each of the plurality of stacked structures CS may be connected to a first word line pad WLP1 at an uppermost position among the plurality of first word line pads WLP1, and a first word line contact WC1 connected to the first word line pad WLP1 at the uppermost position may be connected to the first word lines WL1 at the uppermost position among the plurality of first word lines WL1 through the first word line pad WLP1 at the uppermost position.

Any second word line contact WC2 among the plurality of second word line contacts WC2 may be connected to the plurality of second word lines WL2 positioned at the same vertical level as a second word line pad WLP2 in contact with a lower surface of the any second word line contact WC2, among the plurality of second word line pads WLP2. In this regard, the plurality of second word lines WL2 connected to the any second word line contact WC2 may have the same vertical level.

The semiconductor device 100 according to one or more embodiments may include a plurality of word line pads WLP that are stacked in the vertical direction (Z direction) on two sides of a plurality of stacked structures CS, may extend in the first horizontal direction (X direction), and may have the same length and the same width. The plurality of word line pads WLP may respectively connect word lines WL positioned at the same vertical level, among a plurality of word lines WL, to a plurality of word line contacts WC. Accordingly, the plurality of word lines WL positioned at the same vertical level, among the plurality of word lines WL included in each of the plurality of stacked structures CS, may not each have an individual word line contact, and thus, the space for forming word line contacts may be saved. As a result, more memory cells may be arranged in the same size, and thus, the degree of integration of the semiconductor device 100 may be improved.

Also, when word line pads of a semiconductor device according to a comparative example are formed in a stair-shaped structure, the process difficulty of the semiconductor device increases due to the necessity of a supporter structure, and the stability of a region where the word line pads are positioned decreases. In contrast, in the semiconductor device 100 of the disclosure, by arranging the plurality of word line pads WLP having the same length and the same width, a supporter structure may be omitted, and thus, the process difficulty of the semiconductor device 100 may be reduced. Also, by reducing the area for forming the plurality of word line pads WLP, the degree of integration of the semiconductor device 100 may be improved.

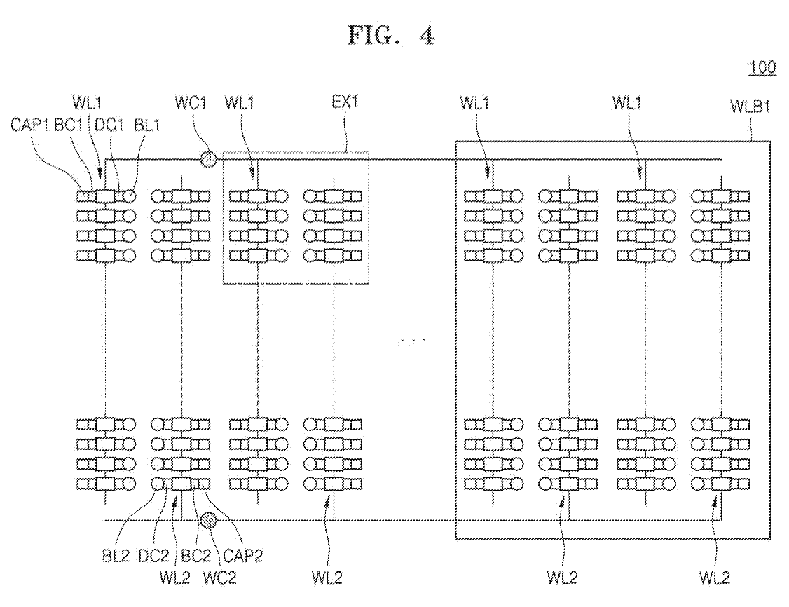

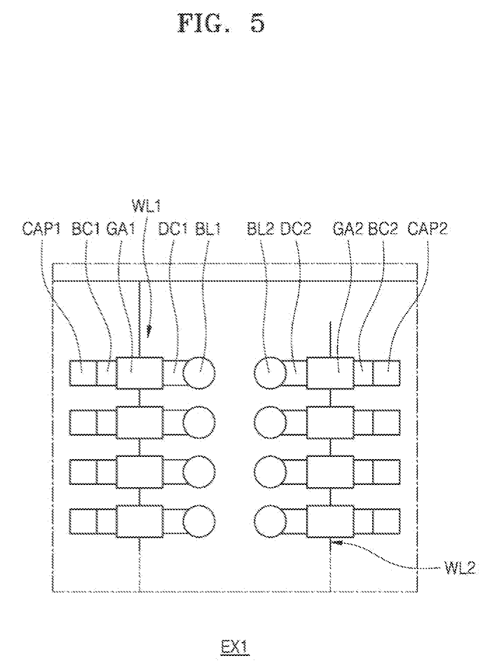

FIG. 4 is a configuration diagram of some components of the semiconductor device 100 according to one or more embodiments. FIG. 5 is an enlarged view of region EX1 of FIG. 4.

Referring to FIGS. 4 and 5, the semiconductor device 100 may include a plurality of first word lines WL1 and a plurality of second word lines WL2. Here, the plurality of first word lines WL1 and the plurality of second word lines WL2 may be word lines included in the plurality of word lines WL (see FIGS. 2 and 3).

The plurality of first word lines WL1 that are stacked or vertically aligned may be arranged in a plurality of columns to be apart from each other in the first horizontal direction (X direction), and the plurality of second word lines WL2 that are stacked or vertically aligned may be arranged in a plurality of columns to be apart from each other in the first horizontal direction (X direction). Also, the plurality of first word lines WL1 and the plurality of second word lines WL2 may be alternately arranged in the first horizontal direction (X direction). For example, when four adjacent word lines among the plurality of word lines included in the semiconductor device 100 are regarded as one word line array unit WLB1, in the one word line array unit WLB1, first and third word lines may correspond to the first word line WL1, and second and fourth word lines may correspond to the second word line WL2. In one or more embodiments, the plurality of first word lines WL1 and the plurality of second word lines WL2 may be positioned at the same vertical level.

The plurality of first word lines WL1 may be connected to a first word line contact WC1, and the plurality of second word lines WL2 may be connected to a second word line contact WC2. Here, the first word line contact WC1 and the second word line contact WC2 may correspond to the plurality of word line contacts WC (see FIGS. 2 and 3).

A plurality of first bit lines BL1 and a plurality of first capacitor structures CAP1 may be arranged on two sides of each of the plurality of first word lines WL1. A plurality of second bit lines BL2 and a plurality of second capacitor structures CAP2 may be arranged on two sides of each of the plurality of second word lines WL2. Also, a first direct contact DC1 may be arranged between each of the plurality of first word lines WL1 and the first bit line BL1. A first buried contact BC1 may be arranged between each of the plurality of first word lines WL1 and the first capacitor structure CAP1. A second direct contact DC2 may be arranged between each of the plurality of second word lines WL2 and the second bit line BL2. A second buried contact BC2 may be arranged between each of the plurality of second word lines WL2 and the second capacitor structure CAP2. Here, the first bit line BL1 and the second bit line BL2 may correspond to the plurality of bit lines BL (see FIGS. 2 and 3), the first capacitor structure CAP1 and the second capacitor structure CAP2 may correspond to the plurality of capacitor structures CAP (see FIGS. 2 and 3), the first direct contact DC1 and the second direct contact DC2 may correspond to the direct contact DC (see FIGS. 2 and 3), and the first buried contact BC1 and the second buried contact BC2 may correspond to the buried contact BC (see FIGS. 2 and 3).

Each of the plurality of first bit lines BL1 and the plurality of first capacitor structures CAP1 may be separate from each other with the first word line WL1 therebetween. The plurality of first bit lines BL1 may be separate from each other in an extension direction of the first word line WL1. The plurality of first capacitor structures CAP1 may be separate from each other in the extension direction of the first word line WL1. Each of the plurality of second bit lines BL2 and the plurality of second capacitor structures CAP2 may be separate from each other with the second word line WL2 therebetween. The plurality of second bit lines BL2 may be separate from each other in an extension direction of the second word line WL2. The plurality of second capacitor structures CAP2 may be separate from each other in the extension direction of the second word line WL2.

In one or more embodiments, the first bit line BL1 and the second bit line BL2 may be in a complementary relationship. Accordingly, the first bit line BL1 may be referred to as a bit line, and the second bit line BL2 may be referred to as a complementary bit line. In this regard, the complementary relationship may denote that electrical signals transmitted to the first bit line BL1 and the second bit line BL2 are complementary.

A portion of each of the plurality of first word lines WL1 that intersects with the first bit line BL1 may be referred to as a first gate GA1. A portion of each of the plurality of second word lines WL2 that intersects with the second bit line BL2 may be referred to as a second gate GA2. The first gate GA1 may constitute a cell transistor of a memory cell in a region where each of the plurality of first word lines WL1 intersects with the first bit line BL1. The second gate GA2 may constitute a cell transistor of a memory cell in a region where each of the plurality of second word lines WL2 intersects with the second bit line BL2.

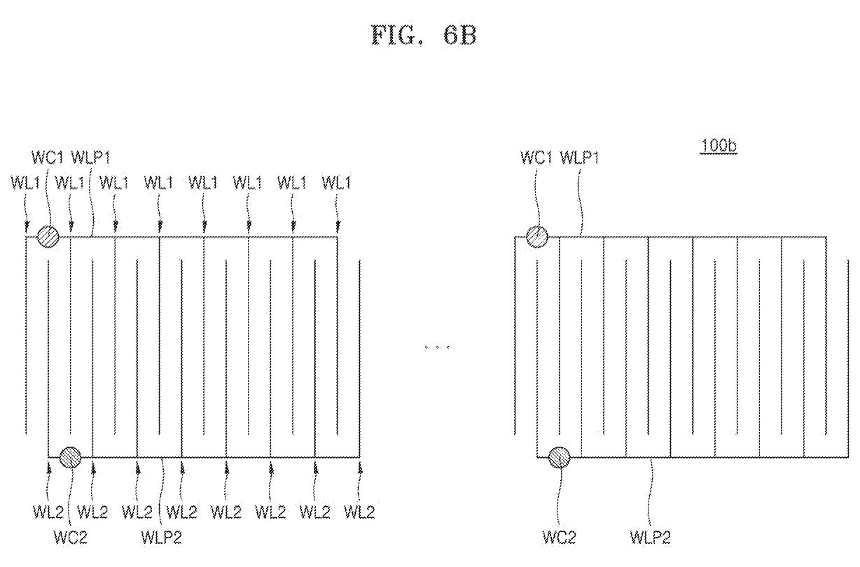

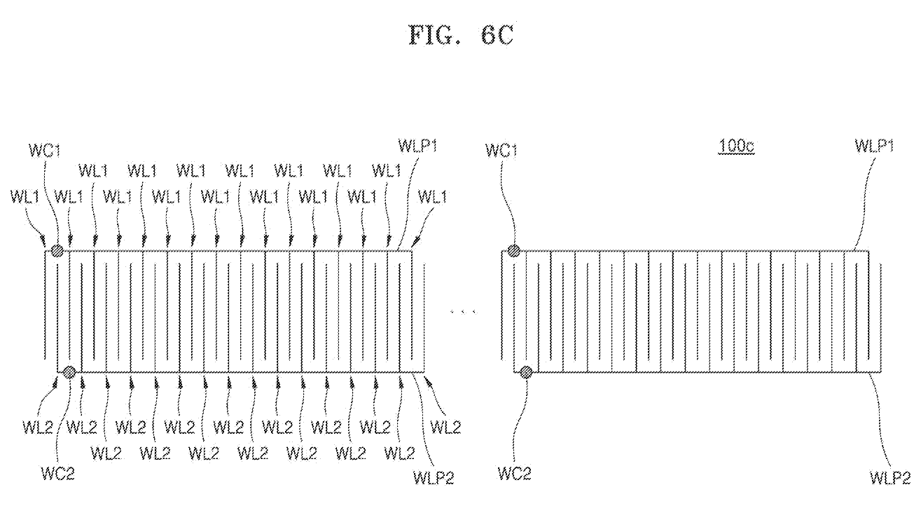

FIGS. 6A, 6B, and 6C are configuration diagrams illustrating some components of semiconductor devices 100a, 100b, and 100c according to one or more embodiments. Respective components of the semiconductor devices 100a, 100b, and 100c illustrated in FIGS. 6A, 6B, and 6C are similar to those of the semiconductor device 100 described with reference to FIGS. 2 to 5, and thus, differences are mainly described below.

Referring to FIG. 6A, the semiconductor device 100a may include a plurality of first word line contacts WC1 and a plurality of second word line contacts WC2 and may have the same configuration as the semiconductor device 100 illustrated in FIGS. 2 to 5, except that four first word lines WL1 selected from among a plurality of first word lines WL1 are connected to each of the plurality of first word line contacts WC1, and four second word lines WL2 selected from among a plurality of second word lines WL2 are connected to each of the plurality of second word line contacts WC2. That is, when the semiconductor device 100a includes 16n first word lines WL1 and 16n second word lines WL2, the semiconductor device 100a may include 4n first word line contacts WC1 and 4n second word line contacts WC2.

Referring to FIG. 6B, the semiconductor device 100b may include a plurality of first word line contacts WC1 and a plurality of second word line contacts WC2 and may have the same configuration as the semiconductor device 100 illustrated in FIGS. 2 to 5, except that eight first word lines WL1 selected from among a plurality of first word lines WL1 are connected to each of the plurality of first word line contacts WC1, and eight second word lines WL2 selected from among a plurality of second word lines WL2 are connected to each of the plurality of second word line contacts WC2. That is, when the semiconductor device 100b includes 16n first word lines WL1 and 16n second word lines WL2, the semiconductor device 100b may include 2n first word line contacts WC1 and 2n second word line contacts WC2.

Referring to FIG. 6C, the semiconductor device 100c may include a plurality of first word line contacts WC1 and a plurality of second word line contacts WC2 and may have the same configuration as the semiconductor device 100 illustrated in FIGS. 2 to 5, except that sixteen first word lines WL1 selected from among a plurality of first word lines WL1 are connected to each of the plurality of first word line contacts WC1, and sixteen second word lines WL2 selected from among a plurality of second word lines WL2 are connected to each of the plurality of second word line contacts WC2. That is, when the semiconductor device 100c includes 16n first word lines WL1 and 16n second word lines WL2, the semiconductor device 100c may include n first word line contacts WC1 and n second word line contacts WC2.

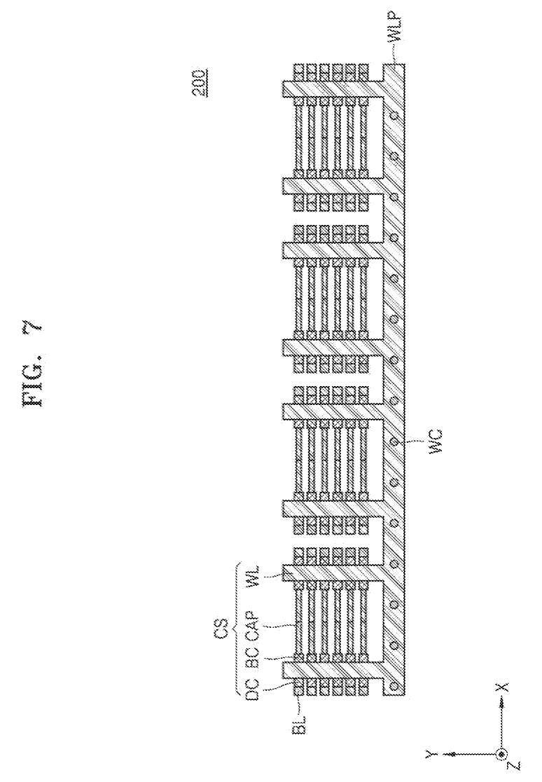

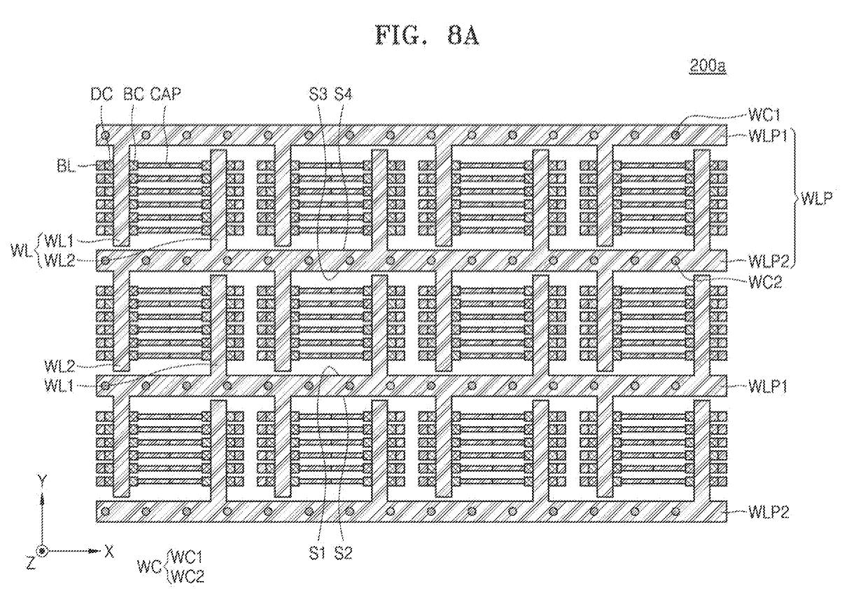

FIG. 7 is a plan view schematically illustrating a semiconductor device 200 according to one or more embodiments. Respective components of the semiconductor device 200 illustrated in FIG. 7 are similar to those of the semiconductor device 100 described with reference to FIGS. 2 to 5, and thus, differences are mainly described below.

Referring to FIG. 7, in a plan view of the semiconductor device 200 of the disclosure, a plurality of word line pads WLP may be arranged only on one side of a stacked structure CS in the second horizontal direction (Y direction).

A plurality of word line pads WLP may be arranged on one side of each of a plurality of word lines WL. The plurality of word line pads WLP may extend in the first horizontal direction (X direction) on one side of each of the plurality of word lines WL. The plurality of word line pads WLP may be stacked in the vertical direction (Z direction). Each of the plurality of word line pads WLP that are stacked may be positioned at the same vertical level as each of the plurality of word lines WL that are stacked. For example, a word line pad WLP at an uppermost position among the plurality of word line pads WLP may be positioned at the same vertical level as a word line WL at an uppermost position among the plurality of word lines WL, and a word line pad WLP at a lowermost position among the plurality of word line pads WLP may be positioned at the same vertical level as a word line WL at a lowermost position among the plurality of word lines WL.

Word lines WL positioned at the same vertical level, among the plurality of word lines WL included in each of the plurality of stacked structures CS, may be connected to a word line pad WLP positioned at the same vertical level. For example, a word line WL at an uppermost position among the plurality of word lines WL included in each of the plurality of stacked structures CS may be connected to a word line pad WLP at an uppermost position among the plurality of word line pads WLP.

The plurality of word line pads WLP may each extend in the first horizontal direction (X direction on one side of the plurality of stacked structures CS. The plurality of word line pads WLP may have the same length and the same width. For example, even away from the upper surface of the substrate 110 in the vertical direction (Z direction), the plurality of word line pads WLP may have the same length in the first horizontal direction (X direction). Also, even away from the upper surface of the substrate 110 in the vertical direction (Z direction), the plurality of word line pads WLP may have the same width in the second horizontal direction (Y direction).

A plurality of word line contacts WC may respectively be arranged on the plurality of word line pads WLP. The plurality of word line contacts WC may respectively pass through the plurality of word line pads WLP in the vertical direction (Z direction). The plurality of word line contacts WC may pass through the plurality of word line pads WLP, and lower surfaces of the plurality of word line contacts WC may each be in contact with one word line pad WLP among the plurality of word line pads WLP. In this regard, the plurality of word line contacts WC may have different lengths in the vertical direction (Z direction). Accordingly, the plurality of word line contacts WC may pass through different numbers of the plurality of word line pads WLP in the vertical direction (Z direction).

The plurality of word line contacts WC may be separate from each other in the first horizontal direction (X direction) and may respectively be connected to the plurality of word lines WL through the plurality of word line pads WLP.

Any word line contact WC among the plurality of word line contacts WC may be connected to the plurality of word lines WL positioned at the same vertical level as a word line pad WLP in contact with a lower surface of the any word line contact WC, among the plurality of word line pads WLP. For example, a word lines WL at an uppermost position among the plurality of word lines WL included in each of the plurality of stacked structures CS may be connected to a word line pad WLP at an uppermost position among the plurality of word line pads WLP, and a word line contact WC connected to the word line pad WLP at the uppermost position may be connected to the word lines WL at the uppermost position among the plurality of word lines WL through the word line pad WLP at the uppermost position.

The semiconductor device 200 according to one or more embodiments may include a plurality of word line pads WLP that are stacked in the vertical direction (Z direction) on one side of a plurality of stacked structures CS, extend in the first horizontal direction (X direction), and have the same length and the same width. The plurality of word line pads WLP may respectively connect word lines WL positioned at the same vertical level, among a plurality of word lines WL, to a plurality of word line contacts WC. Accordingly, the plurality of word lines WL positioned at the same vertical level, among the plurality of word lines WL included in each of the plurality of stacked structures CS, may not each have an individual word line contact, and thus, the space for forming word line contacts may be saved. As a result, more memory cells may be arranged in the same size, and thus, the degree of integration of the semiconductor device 200 may be improved.

Also, when word line pads of a semiconductor device according to a comparative example are formed in a stair-shaped structure, the process difficulty of the semiconductor device increases due to the necessity of a supporter structure, and the stability of a region where the word line pads are positioned decreases. In contrast, in the semiconductor device 200 of the disclosure, by arranging the plurality of word line pads WLP having the same length and the same width, a supporter structure may be omitted, and thus, the process difficulty of the semiconductor device 200 may be reduced. Also, by reducing the area for forming the plurality of word line pads WLP, the degree of integration of the semiconductor device 200 may be improved.

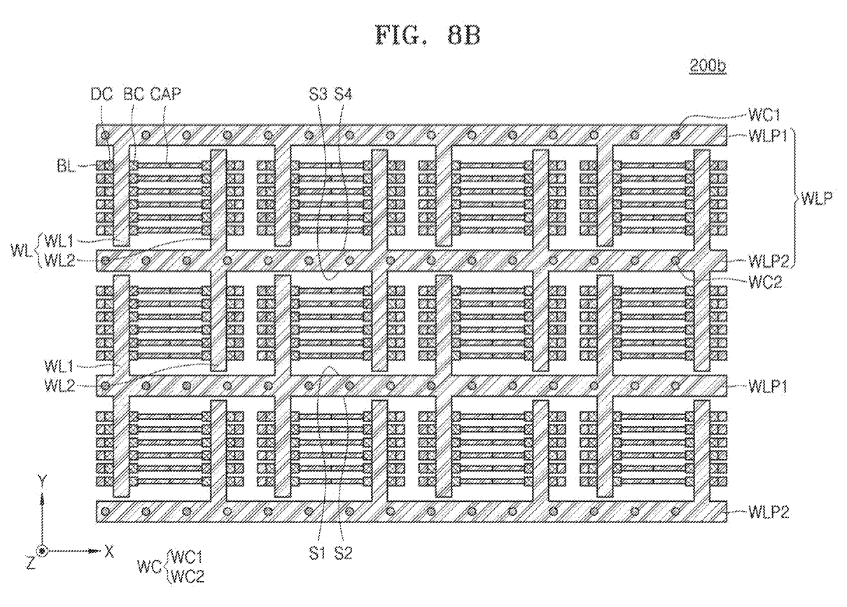

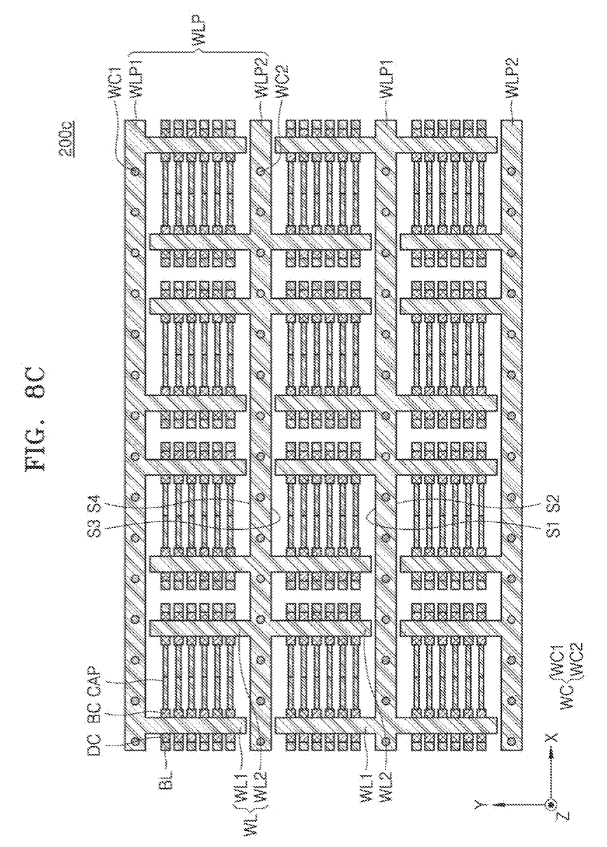

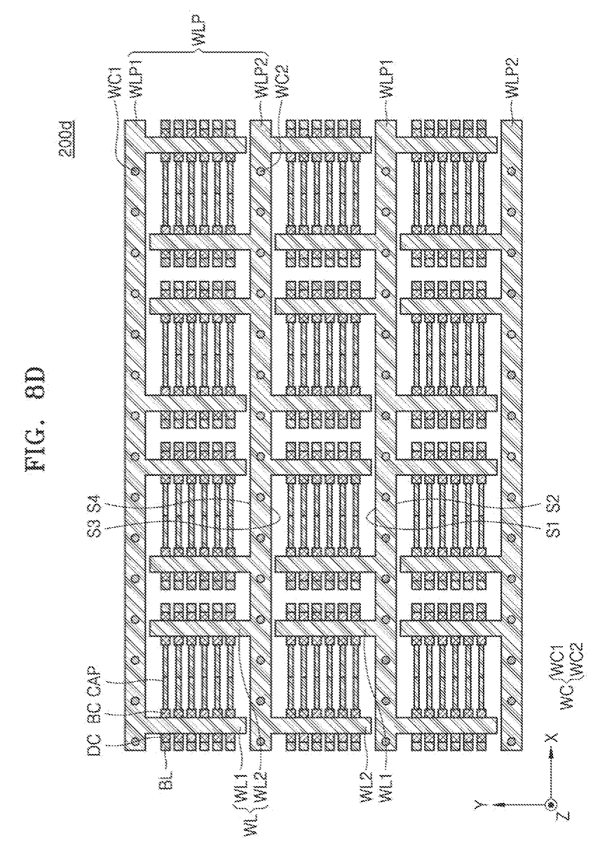

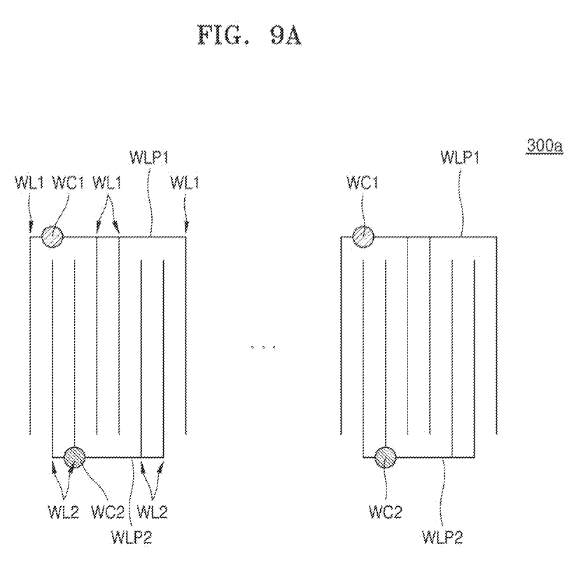

FIGS. 8A to 8D are plan views schematically illustrating semiconductor devices 200a, 200b, 200c, and 200d according to one or more embodiments. Respective components of the semiconductor devices 200a, 200b, 200c, and 200d illustrated in FIGS. 8A to 8D are similar to those of the semiconductor device 100 described with reference to FIGS. 2 to 5, and thus, differences are mainly described below.

Referring to FIGS. 8A to 8D, a plurality of word line pads WLP may include a plurality of first word line pads WLP1 and a plurality of second word line pads WLP2. The plurality of first word line pads WLP1 may be arranged in a plurality of columns to be apart from each other in the second horizontal direction (Y direction), and the plurality of second word line pads WLP2 may be arranged in a plurality of columns to be apart from each other in the second horizontal direction (Y direction). Also, the plurality of first word line pads WLP1 and the plurality of second word line pads WLP2 may be alternately arranged in the second horizontal direction (Y direction).

The plurality of first word line pads WLP1 may each include a first side surface S1 and a second side surface S2. In this regard, the second side surface S2 may refer to a surface opposite to the first side surface S1 in the second horizontal direction (Y direction). The plurality of first word lines WL1 may each be in contact with the first side surface S1 or the second side surface S2.

The plurality of second word line pads WLP2 may each include a third side surface S3 and a fourth side surface S4. In this regard, the fourth side surface S4 may refer to a surface opposite to the third side surface S3 in the second horizontal direction (Y direction). The third side surfaces S3 of the plurality of second word line pads WLP2 may face the first side surfaces S1 of the plurality of first word line pads WLP1, and the fourth side surfaces S4 of the plurality of second word line pads WLP2 may face the second side surfaces S2 of the plurality of second word line pads WLP2. The plurality of second word lines WL2 may each be in contact with the third side surface S3 or the fourth side surface S4.

Referring to FIG. 8A, the semiconductor device 200a of the disclosure may include a plurality of first word lines WL1 and a plurality of second word lines WL2 that are arranged in a plurality of columns to be apart from each other in the first horizontal direction (X direction). The plurality of first word lines WL1 and the plurality of second word lines WL2 may be alternately arranged in the first horizontal direction (X direction).

In a plan view, the plurality of first word lines WL1 in contact with the first side surfaces S1 of the plurality of first word line pads WLP1 and the plurality of first word lines WL1 in contact with the second side surfaces S2 of the plurality of first word line pads WLP1 may be arranged in asymmetrical structures in the second horizontal direction (Y direction) with respect to the plurality of first word line pads WLP1 as central axes.

In a plan view, the plurality of second word lines WL2 in contact with the third side surfaces S3 of the plurality of second word line pads WLP2 and the plurality of second word lines WL2 in contact with the fourth side surfaces S4 of the plurality of second word line pads WLP2 may be arranged in asymmetrical structures in the second horizontal direction (Y direction) with respect to the plurality of second word line pads WLP2 as central axes.

Referring to FIG. 8B, the semiconductor device 200b of the disclosure may include a plurality of first word lines WL1 and a plurality of second word lines WL2 that are arranged in a plurality of columns to be apart from each other in the first horizontal direction (X direction). The plurality of first word lines WL1 and the plurality of second word lines WL2 may be alternately arranged in the first horizontal direction (X direction).

In a plan view, the plurality of first word lines WL1 in contact with the first side surfaces S1 of the plurality of first word line pads WLP1 and the plurality of first word lines WL1 in contact with the second side surfaces S2 of the plurality of first word line pads WLP1 may be arranged in symmetrical structures in the second horizontal direction (Y direction) with respect to the plurality of first word line pads WLP1 as central axes.

In a plan view, the plurality of second word lines WL2 in contact with the third side surfaces S3 of the plurality of second word line pads WLP2 and the plurality of second word lines WL2 in contact with the fourth side surfaces S4 of the plurality of second word line pads WLP2 may be arranged in symmetrical structures in the second horizontal direction (Y direction) with respect to the plurality of second word line pads WLP2 as central axes.

Referring to FIG. 8C, the semiconductor device 200c of the disclosure may include a plurality of first word lines WL1 and a plurality of second word lines WL2 that are arranged in a plurality of columns to be apart from each other in the first horizontal direction (X direction). Two of the plurality of first word lines WL1 and two of the plurality of second word lines WL2 may be alternately arranged. For example, two second word lines WL2, two first word lines WL1, and two second word lines WL2 may be sequentially arranged in the horizontal direction.

In a plan view, the plurality of first word lines WL1 in contact with the first side surfaces S1 of the plurality of first word line pads WLP1 and the plurality of first word lines WL1 in contact with the second side surfaces S2 of the plurality of first word line pads WLP1 may be arranged in symmetrical structures in the second horizontal direction (Y direction) with respect to the plurality of first word line pads WLP1 as central axes.

In a plan view, the plurality of second word lines WL2 in contact with the third side surfaces S3 of the plurality of second word line pads WLP2 and the plurality of second word lines WL2 in contact with the fourth side surfaces S4 of the plurality of second word line pads WLP2 may be arranged in symmetrical structures in the second horizontal direction (Y direction) with respect to the plurality of second word line pads WLP2 as central axes.

Referring to FIG. 8D, the semiconductor device 200d of the disclosure may include a plurality of first word lines WL1 and a plurality of second word lines WL2 that are arranged in a plurality of columns to be apart from each other in the first horizontal direction (X direction). Two of the plurality of first word lines WL1 and two of the plurality of second word lines WL2 may be alternately arranged. For example, two second word lines WL2, two first word lines WL1, and two second word lines WL2 may be sequentially arranged in the horizontal direction.

In a plan view, the plurality of first word lines WL1 in contact with the first side surfaces S1 of the plurality of first word line pads WLP1 and the plurality of first word lines WL1 in contact with the second side surfaces S2 of the plurality of first word line pads WLP1 may be arranged in asymmetrical structures in the second horizontal direction (Y direction) with respect to the plurality of first word line pads WLP1 as central axes.

In a plan view, the plurality of second word lines WL2 in contact with the third side surfaces S3 of the plurality of second word line pads WLP2 and the plurality of second word lines WL2 in contact with the fourth side surfaces S4 of the plurality of second word line pads WLP2 may be arranged in asymmetrical structures in the second horizontal direction (Y direction) with respect to the plurality of second word line pads WLP2 as central axes.

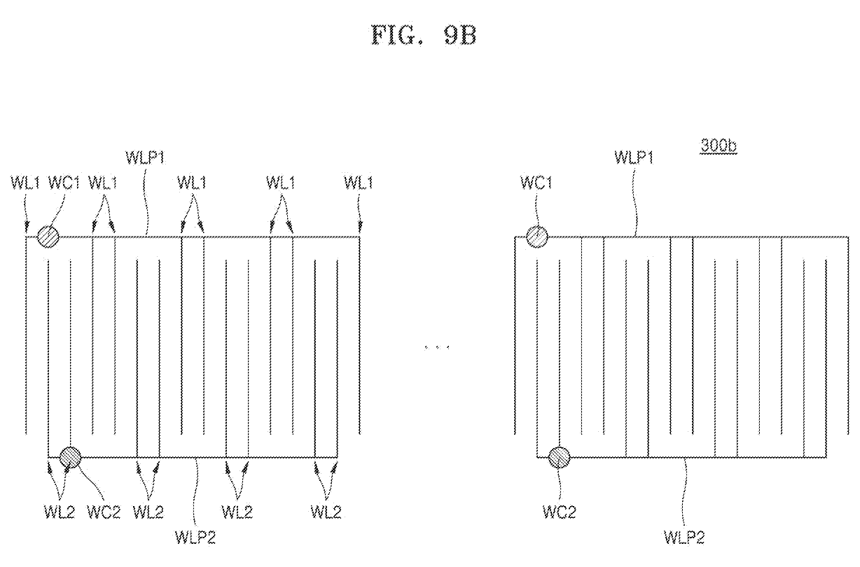

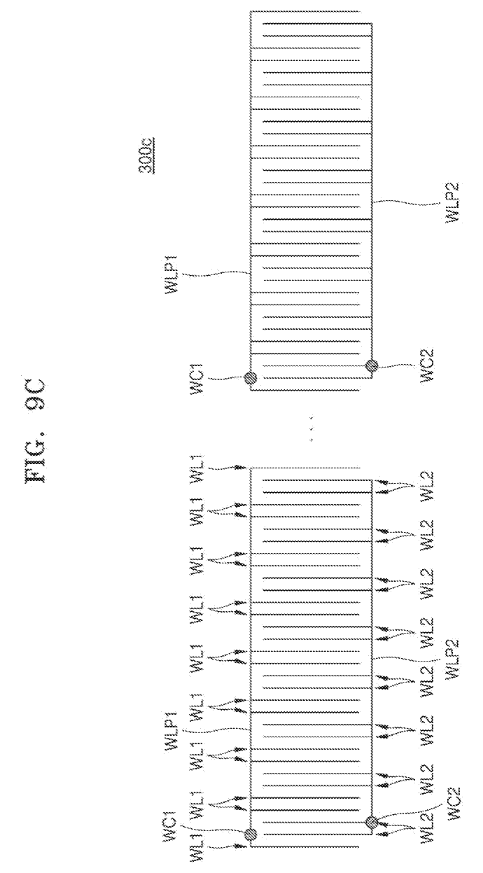

FIGS. 9A, 9B, and 9C are configuration diagrams illustrating some components of semiconductor devices 300a, 300b, and 300c according to one or more embodiments.

Respective components of the semiconductor devices 300a, 300b, and 300c illustrated in FIGS. 9A, 9B, and 9C are similar to those of the semiconductor device 100 described with reference to FIGS. 2 to 5, and thus, differences are mainly described below.

Referring to FIG. 9A, the semiconductor device 300a may include a plurality of first word line contacts WC1 and a plurality of second word line contacts WC2, wherein four first word lines WL1 selected from among a plurality of first word lines WL1 may be connected to each of the plurality of first word line contacts WC1, and four second word lines WL2 selected from among a plurality of second word lines WL2 may be connected to each of the plurality of second word line contacts WC2. When the semiconductor device 300a includes 16n first word lines WL1 and 16n second word lines WL2, the semiconductor device 300a may include 4n first word line contacts WC1 and 4n second word line contacts WC2.

In one or more embodiments, the plurality of first word lines WL1 and the plurality of second word lines WL2 may be alternately arranged. In this regard, two of the plurality of first word lines WL1 and two of the plurality of second word lines WL2 may be alternately arranged. For example, two second word lines WL2, two first word lines WL1, and two second word lines WL2 may be sequentially arranged in the horizontal direction.

Referring to FIG. 9B, the semiconductor device 300b may include a plurality of first word line contacts WC1 and a plurality of second word line contacts WC2, wherein eight first word lines WL1 selected from among a plurality of first word lines WL1 may be connected to each of the plurality of first word line contacts WC1, and eight second word lines WL2 selected from among a plurality of second word lines WL2 may be connected to each of the plurality of second word line contacts WC2. When the semiconductor device 300b includes 16n first word lines WL1 and 16n second word lines WL2, the semiconductor device 300b may include 2n first word line contacts WC1 and 2n second word line contacts WC2.

In one or more embodiments, the plurality of first word lines WL1 and the plurality of second word lines WL2 may be alternately arranged. In this regard, two of the plurality of first word lines WL1 and two of the plurality of second word lines WL2 may be alternately arranged. For example, two second word lines WL2, two first word lines WL1, and two second word lines WL2 may be sequentially arranged in the horizontal direction.

Referring to FIG. 9C, the semiconductor device 300c may include a plurality of first word line contacts WC1 and a plurality of second word line contacts WC2, wherein sixteen first word lines WL1 selected from among a plurality of first word lines WL1 may be connected to each of the plurality of first word line contacts WC1, and sixteen second word lines WL2 selected from among a plurality of second word lines WL2 may be connected to each of the plurality of second word line contacts WC2. When the semiconductor device 300c includes 16n first word lines WL1 and 16n second word lines WL2, the semiconductor device 300c may include n first word line contacts WC1 and n second word line contacts WC2.

In one or more embodiments, the plurality of first word lines WL1 and the plurality of second word lines WL2 may be alternately arranged. In this regard, two of the plurality of first word lines WL1 and two of the plurality of second word lines WL2 may be alternately arranged. For example, two second word lines WL2, two first word lines WL1, and two second word lines WL2 may be sequentially arranged in the horizontal direction.

At least one of the components, elements, modules, units, or the like (collectively "components" in this paragraph) represented by a block or an equivalent indication (collectively “block”) in the above embodiments including the drawings such as FIG. 1, for example, address buffer, address decoder, data i/o circuit, control circuit, sense amplifier, command decoder, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While the disclosure has been particularly shown and described with reference to one or more embodiments thereof, it will be understood that various changes in form and details may be made therein without departing from the spirit and scope of the following claims.

What is claimed is:

1. A semiconductor device comprising:
a substrate;
a plurality of word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction;
a plurality of bit lines extending in the vertical direction and separate from each other in the second horizontal direction on a first side of the plurality of word lines;
a plurality of capacitor structures extending in the first horizontal direction and separate from each other in the second horizontal direction on a second side of the plurality of word lines, the second side of the plurality of word lines being opposite to the first side of the plurality of word lines; and
a plurality of word line pads separate from each other in the vertical direction, extending in the first horizontal direction, and respectively connected to the plurality of word lines,
wherein the plurality of word line pads have a same length in the first horizontal direction.

2. The semiconductor device of claim 1, wherein a word line positioned at a first vertical level, among the plurality of word lines, is connected to a word line pad positioned at the first vertical level, among the plurality of word line pads.

3. The semiconductor device of claim 1, wherein the plurality of word line pads have a same width in the second horizontal direction.

4. The semiconductor device of claim 1, further comprising a plurality of word line contacts separate from each other in the first horizontal direction and connected to the plurality of word line pads,
wherein a lower surface of a first word line contact among the plurality of word line contacts is in contact with a first word line pad among the plurality of word line pads, and
wherein the first word line pad is connected to a first group of word lines positioned at a same vertical level, among the plurality of word lines.

5. The semiconductor device of claim 4,
wherein at least one of the plurality of word line contacts passes through one or more of the plurality of word line pads in the vertical direction, and
wherein a first word line contact among the plurality of word line contacts and a second word line contact among the plurality of word line contacts each pass through a different number of word line pads among the plurality of word line pads.

6. The semiconductor device of claim 1,
wherein the plurality of word line pads comprise a plurality of first word line pads and a plurality of second word line pads separate from each other in the second horizontal direction,
wherein the plurality of first word line pads and the plurality of second word line pads extend in the first horizontal direction, and
wherein the plurality of bit lines and the plurality of capacitor structures are between the plurality of first word line pads and the plurality of second word line pads.

7. The semiconductor device of claim 6, wherein the plurality of word lines comprise:
a plurality of first word lines respectively connected to the plurality of first word line pads; and
a plurality of second word lines respectively connected to the plurality of second word line pads.

8. The semiconductor device of claim 7, wherein the plurality of first word lines and the plurality of second word lines are alternately arranged in the first horizontal direction.

9. The semiconductor device of claim 7, further comprising:
a plurality of first word line contacts, wherein at least one of the plurality of first word line contacts passes through one or more of the plurality of first word line pads; and
a plurality of second word line contacts, wherein at least one of the plurality of second word line contacts passes through one or more of the plurality of second word line pads,
wherein each of the plurality of first word line contacts are respectively connected to one or more first word lines positioned at a same vertical level, among the plurality of first word lines, and
wherein each of the plurality of second word line contacts are respectively connected to one or more second word lines positioned at a same vertical level, among the plurality of second word lines.

10. A semiconductor device comprising:
a substrate;
a plurality of first word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction;
a plurality of second word lines extending in the second horizontal direction and arranged alternately with the plurality of first word lines in the first horizontal direction;
a plurality of bit lines extending in the vertical direction and separate from each other in the second horizontal direction;
a plurality of capacitor structures extending in the first horizontal direction and separate from each other in the second horizontal direction;
a plurality of first word line pads separate from each other in the vertical direction, wherein each of the plurality of first word line pads extends in the first horizontal direction and is respectively connected to the plurality of first word lines; and
a plurality of second word line pads separate from each other in the vertical direction, wherein each of the plurality of second word line pads extends in the first horizontal direction and is respectively connected to the plurality of second word lines,
wherein the plurality of first word line pads and the plurality of second word line pads are separate from each other in the second horizontal direction,
wherein the plurality of bit lines and the plurality of capacitor structures are between the plurality of first word line pads and the plurality of second word line pads,
wherein the plurality of first word line pads have a same length in the first horizontal direction, and
wherein the plurality of second word line pads have a same length in the first horizontal direction.

11. The semiconductor device of claim 10, wherein the plurality of first word line pads and the plurality of second word line pads are alternately arranged in the second horizontal direction.

12. The semiconductor device of claim 10, further comprising:
a plurality of first word line contacts, wherein one or more of the plurality of first word line contacts pass through one or more of the plurality of first word line pads; and
a plurality of second word line contacts, wherein one or more of the plurality of second word line contacts pass through one or more of the plurality of second word line pads,
wherein each of the plurality of first word line contacts are respectively connected to one or more of the plurality of first word lines positioned at a same vertical level, among the plurality of first word lines, and
wherein each of the plurality of second word line contacts are respectively connected to one or more of the plurality of second word lines positioned at a same vertical level, among the plurality of second word lines.

13. The semiconductor device of claim 10,
wherein a first word line positioned at a first specific vertical level, among the plurality of first word lines, is connected to a first word line pad positioned at the first specific vertical level, among the plurality of first word line pads, and
a second word line positioned at a second specific vertical level, among the plurality of second word lines, is connected to a second word line pad positioned at the second specific vertical level, among the plurality of second word line pads.

14. The semiconductor device of claim 10,
wherein the plurality of first word line pads each comprise a first side surface and a second side surface opposite to the first side surface, and
wherein the plurality of first word lines are each in contact with the first side surface or the second side surface of a first word line pad of the plurality of first word line pads.

15. The semiconductor device of claim 14, wherein a first subset of the plurality of first word lines in contact with the first side surfaces of the plurality of first word line pads and a second subset of the plurality of first word lines in contact with the second side surfaces of the plurality of first word line pads are arranged in symmetrical structures in the second horizontal direction with respect to the plurality of first word line pads.

16. The semiconductor device of claim 14, wherein a first subset of the plurality of first word lines in contact with the first side surfaces of the plurality of first word line pads and a second subset of the plurality of first word lines in contact with the second side surfaces of the plurality of first word line pads are arranged in asymmetrical structures in the second horizontal direction with respect to the plurality of first word line pads.

17. The semiconductor device of claim 14,
wherein the plurality of second word line pads each include a third side surface and a fourth side surface opposite to the third side surface, and
wherein the plurality of second word lines are each in contact with the third side surface or the fourth side surface of a second word line pad of the plurality of second word line pads.

18. A semiconductor device comprising:
a substrate;
a peripheral circuit structure on the substrate; and
a cell array structure on the peripheral circuit structure, the cell array structure comprising a plurality of stacked structures,
wherein each of the plurality of stacked structures comprises:
a plurality of word lines separate from each other in a vertical direction and in a first horizontal direction and extending in a second horizontal direction, the vertical direction being perpendicular to an upper surface of the substrate, the first horizontal direction being parallel to the upper surface of the substrate, and the second horizontal direction intersecting with the first horizontal direction;
a plurality of bit lines extending in the vertical direction and separate from each other in the second horizontal direction on a first side of the plurality of word lines; and
a plurality of capacitor structures extending in the first horizontal direction and separate from each other in the second horizontal direction on a second side of the plurality of word lines, the second side of the plurality of word lines being opposite to the first side of the plurality of word lines, and
wherein the cell array structure further comprises:
a plurality of word line pads separate from each other in the vertical direction, wherein the plurality of word line pads are on two sides of the plurality of stacked structures in the second horizontal direction, extend to have a same length in the first horizontal direction, and are respectively connected to the plurality of word lines; and
a plurality of word line contacts separate from each other in the first horizontal direction and respectively connected to the plurality of word lines through the plurality of word line pads.

19. The semiconductor device of claim 18, wherein each of the plurality of word line contacts are respectively connected to two or more word lines positioned at a same vertical level, among the plurality of word lines.

20. The semiconductor device of claim 18,
wherein at least one of the plurality of word line contacts passes through one or more of the plurality of word line pads in the vertical direction, and
wherein a first word line contact among the plurality of word line contacts and a second word line contact among the plurality of word line contacts each pass through a different number of word line pads among the plurality of word line pads.
